(19) United States
(12) Patent Application Publication
(10) Pub. No.: US 2020/0194512 A1
(43) Pub. Date: Jun. 18, 2020

(54) ORGANIC LIGHT-EMITTING DIODE PIXEL STRUCTURE

(71) Applicant: Wuhan China Star Optoelectronics Semiconductor Display Technology Co., Ltd., Wuhan (CN)

(72) Inventor: Yi WANG, Wuhan (CN)

(21) Appl. No.: 16/323,528

(22) PCT Filed: Jan. 3, 2019
(86) PCT No.: PCT/CN2019/070269

§ 371 Date: Feb. 6, 2019

(30) Foreign Application Priority Data
Dec. 18, 2018 (CN) 201811548758.3

(51) Int. Cl. H01L 27/32

(52) U.S. Cl. CPC H01L 27/3218; H01L 27/3216

(57) ABSTRACT

An organic light-emitting diode (OLED) pixel structure includes a plurality of first sub-pixel groups arranged along a first pixel row, a plurality of second sub-pixel groups arranged alternately with the first sub-pixel groups along the first pixel row, and a plurality of third sub-pixel groups arranged along a second pixel row. Each of the first sub-pixel groups includes at least two first sub-pixels. Each of the second sub-pixel groups includes at least two second sub-pixels, and each of the third sub-pixel groups includes at least one third sub-pixel. The third sub-pixel is adjacent to one of the first sub-pixels and one of the second sub-pixels.

### FIELD OF DISCLOSURE

The present disclosure relates to the field of display technologies, and in particular, to an organic light-emitting diode (OLED) pixel structure.

### BACKGROUND

An OLED display panel includes a plurality of pixels, and each pixel includes three types of sub-pixels: a red sub-pixel, a green sub-pixel, and a blue sub-pixel. The three types of sub-pixels have different organic light-emitting materials. During manufacturing, three different organic materials need to be evaporated on the three types of sub-pixels, that is, the red, green, and blue sub-pixels, at corresponding positions through metal mask plates. A metal mask plate corresponding to sub-pixels of the same color needs a group of openings. Then, a mixture ratio of a combination of the three colors is adjusted to generate true colors.

With development of display technologies, people have increasingly higher requirements on resolution and brightness of display screens. For a high-resolution display panel, a distance between sub-pixel light-emitting regions is required to be smaller due to a higher requirement on the resolution. However, limited by a manufacture process of metal masks, it is impossible to obtain more pixels per inch. A decrease in pitches between the three types of sub-pixels, that is, the red, green, and blue sub-pixels, causes color mixture of sub-pixels of different colors during evaporation of the sub-pixels, thereby decreasing an image display performance. Therefore, the resolution of the OLED pixel in the current technology needs to be improved.

### SUMMARY OF DISCLOSURE

The present disclosure provides an OLED pixel structure, to resolve the problem that in the current pixel structure, if the resolution is improved by decreasing pitches between three types of sub-pixels, that is, red, green, and blue sub-pixels, color mixture occurs in sub-pixels of different colors during evaporation of the sub-pixels, thereby decreasing an image display performance.

In order to resolve the foregoing problem, the present disclosure provides the following technical solutions:

The present disclosure provides an OLED pixel structure, including: a plurality of first sub-pixel groups arranged along a first pixel row, a plurality of second sub-pixel groups arranged alternately with the first sub-pixel groups along the first pixel row, and a plurality of third sub-pixel groups arranged along a second pixel row. Each of the first sub-pixel groups includes at least two adjacent first sub-pixels that are distributed at an interval. Each of the second sub-pixel groups includes at least two adjacent second sub-pixels that are distributed at an interval. Each of the third sub-pixel groups includes at least one third sub-pixel. The first pixel row and the second pixel row are arranged alternately. The third sub-pixel is adjacent to one of the first sub-pixels and one of the second sub-pixels. The first sub-pixels and the second sub-pixels include rhombic, and the third sub-pixel includes circular. In a pixel row direction, the third sub-pixel groups are staggered relative to the first sub-pixel groups and the second sub-pixel groups.

In at least one embodiment of the present disclosure, the first sub-pixel groups and the second sub-pixel groups are arranged along a plurality of first pixel columns. The third sub-pixel groups are arranged along a plurality of second pixel columns. The first pixel columns and the second pixel columns are arranged alternately.

In at least one embodiment of the present disclosure, a central line between adjacent first sub-pixel group and second sub-pixel group in the same first pixel row coincides with one of the second pixel columns.

In at least one embodiment of the present disclosure, each of the first sub-pixel groups includes four first sub-pixels, and the four first sub-pixels are arranged in a square matrix.

In at least one embodiment of the present disclosure, each of the second sub-pixel groups includes four second sub-pixels, and the four second sub-pixels are arranged in a square matrix.

In at least one embodiment of the present disclosure, each of the third sub-pixel groups includes two adjacent third sub-pixels that are distributed at an interval, and the two third sub-pixels are arranged along a pixel column.

In at least one embodiment of the present disclosure, structures of the second sub-pixel groups are the same as structures of the first sub-pixel groups.

In at least one embodiment of the present disclosure, the first sub-pixels, the second sub-pixels, and the third sub-pixel are red sub-pixels, blue sub-pixels, and a green sub-pixel respectively.

The present disclosure further provides another OLED pixel structure, including: a plurality of first sub-pixel groups, a plurality of second sub-pixel groups, and a plurality of third sub-pixel groups. The first sub-pixel groups are arranged along a first pixel row. Each of the first sub-pixel groups includes at least two adjacent first sub-pixels that are arranged at an interval. The second sub-pixel groups are arranged alternately with the first sub-pixel groups along the first pixel row. Each of the second sub-pixel groups includes at least two adjacent second sub-pixels that are arranged at an interval. The third sub-pixel groups are arranged along a second pixel row, and each of the third sub-pixel groups include at least one third sub-pixel. The first pixel row and the second pixel row are arranged alternately, and the third sub-pixel is adjacent to one of the first sub-pixels and one of the second sub-pixels.

In at least one embodiment of the present disclosure, in a pixel row direction, the third sub-pixel groups are staggered relative to the first sub-pixel groups and the second sub-pixel groups.

In at least one embodiment of the present disclosure, the first sub-pixel groups and the second sub-pixel groups are arranged along a plurality of first pixel columns, the third sub-pixel groups are arranged along a plurality of second pixel columns, and the first pixel columns are arranged alternately with the second pixel columns.

In at least one embodiment of the present disclosure, a central line between adjacent first sub-pixel group and second sub-pixel group in the same first pixel row coincides with one of the second pixel columns.

In at least one embodiment of the present disclosure, each of the first sub-pixel groups includes four first sub-pixels, and the four first sub-pixels are arranged in a square matrix.

In at least one embodiment of the present disclosure, each of the second sub-pixel groups includes four second sub-pixels, and the four second sub-pixels are arranged in a square matrix.

In at least one embodiment of the present disclosure, each of the third sub-pixel groups includes two adjacent third sub-pixels that are distributed at an interval, and the two third sub-pixels are arranged along a pixel column.

In at least one embodiment of the present disclosure, structures of the second sub-pixel groups are the same as structures of the first sub-pixel groups.

In at least one embodiment of the present disclosure, the first sub-pixels, the second sub-pixel, and the third sub-pixel are red sub-pixels, blue sub-pixel, and a green sub-pixel respectively.

In at least one embodiment of the present disclosure, the first sub-pixels and the second sub-pixels include rhombic, and the third sub-pixel includes circular.

The present disclosure achieves the following advantages: In the present disclosure, an arrangement structure of OLED pixels is changed and pixel sizes are reduced, so that more pixels per inch are obtained, thereby improving the resolution of a panel. Moreover, pitches between sub-pixels of different colors are also increased, thereby helping reduce color mixture.

### BRIEF DESCRIPTION OF DRAWINGS

To describe the technical solutions of the embodiments or the prior art more clearly, the accompanying drawings for illustrating the embodiments or the prior art will be introduced briefly in the following. Apparently, the drawings in the following description are only some embodiments of the present disclosure, and a person of ordinary skill in the art may obtain other drawings based on these accompanying drawings without creative efforts.

FIG. 1 is a schematic diagram of an OLED pixel structure according to a first embodiment of the present disclosure.

FIG. 2 is a schematic diagram of an OLED pixel structure according to a second embodiment of the present disclosure.

### DETAILED DESCRIPTION

The description of the following embodiments is made with reference to the accompanying drawings, and is used to illustrate particular embodiments that can be implemented of the present disclosure. The directional terms mentioned in the present disclosure, such as “upper”, “lower”, “front”, “rear”, “left”, “right”, “inner”, “outer”, and “side surface”, are merely directions with reference to the accompanying drawings. Therefore, the used directional terms are used for illustration and comprehension of the present disclosure, but are not intended to limit the present disclosure. In the drawings, units with similar structures are represented by using identical reference numerals.

In view of the problem that in the current OLED pixel structure, if the resolution is improved by decreasing pitches between three types of sub-pixels, that is, red, green, and blue sub-pixels, color mixture occurs in sub-pixels of different colors during evaporation of the sub-pixels, thereby decreasing display, embodiments of the present disclosure can resolve this defect.

### First Embodiment

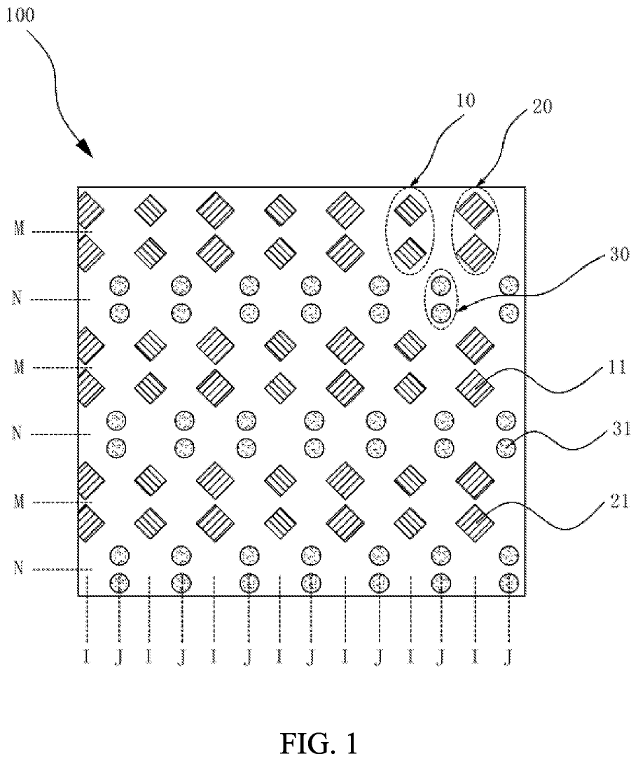

As shown in FIG. 1, the present disclosure provides an OLED pixel structure 100, including a plurality of first sub-pixel groups 10, a plurality of second sub-pixel groups 20, and a plurality of third sub-pixel groups 30. The first sub-pixel groups 10 and the second sub-pixel groups 20 are arranged alternately along a plurality of first pixel rows M. The third sub-pixel groups 30 are arranged along a plurality of second pixel rows N. The first pixel rows M and the second pixel rows N are arranged alternately.

The first sub-pixel groups 10 each include at least two adjacent first sub-pixels 11 that are distributed at an interval. The second sub-pixel groups 20 each include at least two adjacent second sub-pixels 21 that are distributed at an interval. The third sub-pixel groups 30 each include at least one third sub-pixel 31.

Each third sub-pixel 31 is adjacent to one first sub-pixel 11 and one second sub-pixel 21. One first sub-pixel 11, one second sub-pixel 21, and one third sub-pixel 31 that are adjacent to each other form one pixel.

In a pixel row direction, the third sub-pixel groups 30 are staggered relative to the first sub-pixel groups 10 and the second sub-pixel groups 20.

In a pixel column direction, the first sub-pixel groups 10 and the second sub-pixel groups 20 are arranged along a plurality of first pixel columns I, and the third sub-pixel groups are arranged along a plurality of second pixel columns J. The first pixel columns and the second pixel columns are arranged alternately. The pixel row direction is perpendicular to the pixel column direction.

In other embodiments, in the same first sub-pixel column I, the first sub-pixel groups 10 and the second sub-pixel groups 20 may be arranged alternately. In this embodiment, the first sub-pixel groups 10 and the second sub-pixel groups 20 are not arranged alternately in the first sub-pixel column I.

In the same pixel row M, a central line between the adjacent first sub-pixel group 10 and second sub-pixel group 20 coincides with the second pixel column J, that is, a column of the third sub-pixel groups 30 are correspondingly distributed on the central line between the adjacent first sub-pixel group 10 and second sub-pixel group 20.

In this embodiment, the first sub-pixel groups 10 each include two first sub-pixels 11, and the two first sub-pixels 11 are arranged along the pixel column direction.

The second sub-pixel groups 20 each include two second sub-pixels 21, and the two second sub-pixels 21 are arranged along the pixel column direction.

The third sub-pixel groups 30 each include two third sub-pixels 31, and the two third sub-pixels 31 are arranged along the pixel column direction.

Lines connecting centers of one first sub-pixel 11, one second sub-pixel 21, and one third sub-pixel 31 that are adjacent to each other form an isosceles triangle.

The first sub-pixels 11 are rhombic. Two diagonals of each first sub-pixel 11 are in the same directions as the pixel row direction and the pixel column direction respectively. The first sub-pixels 11 are red sub-pixels. The second sub-pixels 21 are rhombic. Two diagonals of each second sub-pixel 21 are in the same directions as the pixel row direction and the pixel column direction respectively. The second sub-pixels 21 are green sub-pixels. The third sub-pixels 31 are circular, and the third sub-pixels 31 are blue sub-pixels. By using this shape design and distribution manner, distances between sub-pixels of different colors can be increased as much as possible, thereby reducing color mixture.

The first sub-pixel groups 10 and the second sub-pixel groups 20 may have identical structures, so as to be evaporated by using the same metal mask plate. The third sub-pixel groups 30 are evaporated by using another metal mask plate.

### Second Embodiment

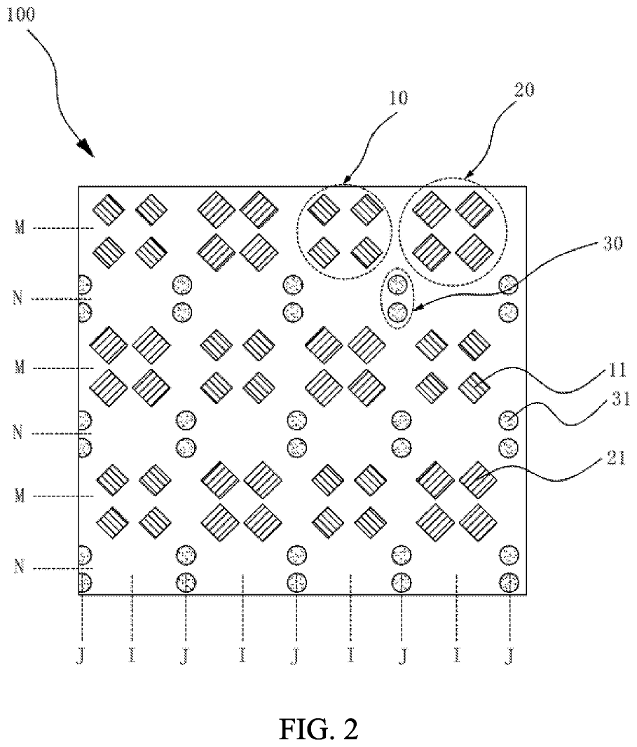

As shown in FIG. 2, a difference from the first embodiment is that in this embodiment, the first sub-pixel groups 10 each include four adjacent first sub-pixels 11 that are distributed at an interval, and the second sub-pixel groups 20 each include four second sub-pixels 21 adjacent first sub-pixels 11 that are distributed at an interval.

In the same first sub-pixel column I, the first sub-pixel groups 10 and the second sub-pixel groups 20 are arranged alternately in this embodiment.

The first sub-pixel groups 10 and the second sub-pixel groups 20 may have identical structures, and may be evaporated by using the same metal mask plate.

The four first sub-pixels 11 in each first sub-pixel group 10 are arranged in a square matrix. The four second sub-pixels 21 in each second sub-pixel group 20 are arranged in a square matrix.

Other structures are all the same as those in the first embodiment. For details, reference can be made to the first embodiment. Details are not described herein again.

The present disclosure achieves the following beneficial effects: in the present disclosure, an arrangement structure of OLED pixels is changed and pixel sizes are reduced, so that more pixels per inch are obtained, thereby improving the resolution of a panel. Moreover, pitches between sub-pixels of different colors are also increased, thereby helping reduce color mixture.

In conclusion, although the present disclosure has been disclosed by using preferred embodiments, the foregoing preferred embodiments are not intended to limit the present disclosure. A person of ordinary skill in the art can make various changes and modifications without departing from the spirit and scope of the present disclosure. Therefore, the protection scope of the present disclosure is subject to the scope defined in the claims.

What is claimed is:

1. An organic light-emitting diode (OLED) pixel structure, comprising:
a plurality of first sub-pixel groups, arranged along a first pixel row, wherein each of the first sub-pixel groups comprises at least two adjacent first sub-pixels that are distributed at an interval;
a plurality of second sub-pixel groups, arranged alternately with the first sub-pixel groups along the first pixel row, wherein each of the second sub-pixel groups comprises at least two adjacent second sub-pixels that are distributed at an interval; and
a plurality of third sub-pixel groups, arranged along a second pixel row, wherein each of the third sub-pixel groups comprises at least one third sub-pixel, wherein the first pixel row and the second pixel row are arranged alternately, and the third sub-pixel is adjacent to one of the first sub-pixels and one of the second sub-pixels;
the first sub-pixels and the second sub-pixels comprise rhombic, and the third sub-pixel comprises circular; and
in a pixel row direction, the third sub-pixel groups are staggered relative to the first sub-pixel groups and the second sub-pixel groups.

2. The OLED pixel structure according to claim 1, wherein the first sub-pixel groups and the second sub-pixel groups are arranged along a plurality of first pixel columns, the third sub-pixel groups are arranged along a plurality of second pixel columns, and the first pixel columns and the second pixel columns are arranged alternately.

3. The OLED pixel structure according to claim 2, wherein a central line between adjacent first sub-pixel group and second sub-pixel group in the same first pixel row coincides with one of the second pixel columns.

4. The OLED pixel structure according to claim 1, wherein each of the first sub-pixel groups comprises four first sub-pixels, and the four first sub-pixels are arranged in a square matrix.

5. The OLED pixel structure according to claim 4, wherein each of the second sub-pixel groups comprises four second sub-pixels, and the four second sub-pixels are arranged in a square matrix.

6. The OLED pixel structure according to claim 5, wherein each of the third sub-pixel groups comprises two adjacent third sub-pixels that are distributed at an interval, and the two third sub-pixels are arranged along a pixel column.

7. The OLED pixel structure according to claim 5, wherein structures of the second sub-pixel groups are the same as structures of the first sub-pixel groups.

8. The OLED pixel structure according to claim 1, wherein the first sub-pixels, the second sub-pixels, and the third sub-pixel are red sub-pixels, blue sub-pixels, and a green sub-pixel respectively.

9. An organic light-emitting diode (OLED) pixel structure, comprising:
a plurality of first sub-pixel groups, arranged along a first pixel row, wherein each of the first sub-pixel groups comprises at least two adjacent first sub-pixels that are arranged at an interval;
a plurality of second sub-pixel groups, arranged alternately with the first sub-pixel groups along the first pixel row, wherein each of the second sub-pixel groups comprises at least two adjacent second sub-pixels that are arranged at an interval;
a plurality of third sub-pixel groups, arranged along a second pixel row, wherein each of the third sub-pixel groups comprises at least one third sub-pixel, wherein the first pixel row and the second pixel row are arranged alternately, and the third sub-pixel is adjacent to one of the first sub-pixels and one of the second sub-pixels.

10. The OLED pixel structure according to claim 9, wherein in a pixel row direction, the third sub-pixel groups are staggered relative to the first sub-pixel groups and the second sub-pixel groups.

11. The OLED pixel structure according to claim 10, wherein the first sub-pixel groups and the second sub-pixel groups are arranged along a plurality of first pixel columns, the third sub-pixel groups are arranged along a plurality of second pixel columns, and the first pixel columns are arranged alternately with the second pixel columns.

12. The OLED pixel structure according to claim 11, wherein a central line between adjacent first sub-pixel group and second sub-pixel group in the same first pixel row coincides with one of the second pixel columns.

13. The OLED pixel structure according to claim 10, wherein each of the first sub-pixel groups comprises four first sub-pixels, and the four first sub-pixels are arranged in a square matrix.

14. The OLED pixel structure according to claim 13, wherein each of the second sub-pixel groups comprises four second sub-pixels, and the four second sub-pixels are arranged in a square matrix.

15. The OLED pixel structure according to claim 14, wherein each of the third sub-pixel groups comprises two adjacent third sub-pixels that are distributed at an interval, and the two third sub-pixels are arranged along a pixel column.

16. The OLED pixel structure according to claim 14, wherein structures of the second sub-pixel groups are the same as structures of the first sub-pixel groups.

17. The OLED pixel structure according to claim 9, wherein the first sub-pixels, the second sub-pixel, and the third sub-pixel are red sub-pixels, blue sub-pixel, and a green sub-pixel respectively.

18. The OLED pixel structure according to claim 9, wherein the first sub-pixels and the second sub-pixels comprise rhombic, and the third sub-pixel comprises circular.
